(19) United States
(12) Patent Application Publication
(10) Pub. No.: US 2005/0239248 A1
(43) Pub. Date: Oct. 27, 2005

(54) Method for manufacturing nonvolatile memory device

(76) Inventor: Seok Kiu Lee, Kyoungki-do (KR)

Correspondence Address: LADAS & PARRY LLP, 224 SOUTH MICHIGAN AVENUE, SUITE 1600, CHICAGO, IL, 60604, US

(21) Appl. No.: 10/999,329

(22) Filed: Nov. 30, 2004

(30) Foreign Application Priority Data
Apr. 22, 2004 (KR) 2004-27892

(51) Int. Cl. H01L 21/336

(52) U.S. Cl. 438/257

(57) ABSTRACT

Disclosed is a method for manufacturing a nonvolatile memory device having an SONOS double gate. The method can improve credibility, as well as device characteristics, by increasing the thickness of the gate insulation film, i.e., the dielectric film, in the SONOS structure of the cell region, as well as in the peripheral circuit region. The method can cause oxidation even to the cell region during gate light etching by etching nitride film in the cell region prior to the gate light etching. This increases the thickness of the gate insulation film of SONOS structure on the lower corner of the gate electrode in the cell region and improves device characteristics and credibility.

### BACKGROUND OF THE INVENTION

1. Field of the Invention

The present invention relates to a method for manufacturing a nonvolatile memory device, and more particularly to a method for forming a double gate insulation film of a nonvolatile memory device having a gate insulation film of oxide/nitride/oxide structure.

2. Description of the Prior Art

As generally known in the art, conventional DRAMs or SRAMs lose stored information when power is not supplied any longer. Specifically, the DRAMs are volatile memory devices having a structure wherein a transistor acts as a switch and a capacitor is adapted to store data in such a manner that internal data is automatically erased when power supply is interrupted. The SRAMs are also volatile memory devices and have a flip-flop type transistor structure wherein data is stored according to the difference in the degree of driving among transistors.

Meanwhile, nonvolatile memory devices, which do not lose stored information even when power supply is interrupted, have been developed by developers who program and supply data or operating systems related to system operation. Nonvolatile memory devices include EPROMs (electrically programmable read only memories), EEPROMs (electrically erasable and programmable read only memories), and flash EEPROMs, all of which are now commercially available. Recently, efforts have been made to commercialize a memory of SONOS (silicon/oxide/nitride/oxide/silicon) structure, which has a gate insulation film having triple structure of oxide/nitride/oxide.

Using such SONOS structure would make it possible to manufacture nonvolatile memory devices which realize low voltage, low power consumption, and high-speed operation and would also be certainly beneficial to the increase in the degree of integration of devices.

The principle of operation of nonvolatile memory devices having such SONOS structure will now be described.

Nonvolatile memory devices having SONOS structure make use of the difference in electrical potential between oxide and nitride films. This is based on a principle wherein, when confined in a nitride film, electrons are not lost but maintain nonvolatile characteristics due to the potential barrier caused by oxide films positioned above and below them, even when power supply is interrupted. Programming can be performed by applying a voltage sufficient for tunneling of electrons through the thin oxide film existing beneath the nitride film. Reading can be performed by identifying the difference in driving current caused by the difference in transistor threshold voltage according to each program with a differential amplifier.

In order to realize such SONOS structure, so-called double gate insulation film structure has been conventionally adopted wherein, the gate insulation film 10a in the cell region has ONO structure and the gate insulation film 10b in the peripheral circuit region has single silicon oxide structure, as shown in FIG. 1.

In FIG. 1, reference numeral 1 refers to a silicon substrate; 2 is a first oxide film; 3 is a nitride film; 4 is a second oxide film; 5 is a third oxide film; 6 is a doped polycrystal silicon film for gate electrode; 7a and 7b are gate insulation films; and 10a and 10b are gate electrodes.

When forming such a transistor as having a gate insulation film 10a of ONO structure in the cell region and a gate insulation film 10b of single oxide structure in the peripheral circuit region, however, there is a limitation in securing device characteristics because oxidation does not occur in the cell region, which has SONOS structure, during gate light oxidation following dry etching of gate electrodes.

Specifically, when a high-selectivity etching process is used as shown in FIG. 1, in order to minimize etching damage in the cell region and prevent the nitride film 3 from being etched, and gate light etching is performed subsequently, the lower corner of the gate electrode 10b in the peripheral region oxidizes and a gate bird's-beak 12 occurs, as shown in FIG. 2. The thickness of the gate insulation film 7b of single oxide structure then increases, while that of the gate insulation film 7a of ONO structure does not increase because the lower corner of the gate electrode 10a in the cell region does not oxidize. As a result, the device is largely prone to hot carrier effect and has increased leak current in the corner of the gate electrode 10a. This degrades device characteristics and credibility.

In FIG. 2, reference numeral 11 refers to a fourth oxide film formed by gate light oxidation.

### SUMMARY OF THE INVENTION

Accordingly, the present invention has been made to solve the above-mentioned problems occurring in the prior art, and an object of the present invention is to provide a method for manufacturing a nonvolatile memory device capable of causing oxidation even to the lower corner of a gate electrode in a cell region during gate light etching for removing gate etching damage.

Another object of the present invention is to provide a method for manufacturing a nonvolatile memory device capable of securing desired device characteristics and credibility by causing oxidation even to the lower corner of a gate electrode in a cell region.

In order to accomplish this object, there is provided a method for manufacturing a nonvolatile memory device comprising the steps of: forming a first oxide film, a nitride film, and a second oxide film on a silicon substrate having a cell region and a peripheral circuit region to form SONOS structure in the cell region; selectively removing the second oxide film and the nitride film in the region having no SONOS structure; forming a third oxide film on the first oxide film in the region having no SONOS structure; forming a gate conductive film on the resulting substrate; etching the gate conductive film and the third and second oxide films to form a gate electrode in the cell region and the peripheral circuit region, respectively; removing the nitride film from the lower corner of the gate electrode, which has been formed in the cell region; and performing gate light oxidation to the resulting substrate so that etching damage during formation of the gate electrode is removed.

The first oxide film is formed to a thickness of 10-50 Å in a thermal oxidation process, the nitride film is formed to a thickness of 50-100 Å, and the second oxide film is formed to a thickness of 30-200 Å in a CVD mode.

The third oxide film has a thickness which, when the thickness of the first oxide film remaining in the peripheral circuit region is added to it, amounts to 35-200 Å.

The gate conductive film is made of any one selected from a group consisting of doped polycrystal silicon film, refractory metal film, and metal silicide film, or a combination thereof.

The gate light oxidation is performed in such a manner that a fourth oxide film is formed on the surface of the gate electrode to a thickness of 50-200 Å.

### BRIEF DESCRIPTION OF THE DRAWINGS

The above and other objects, features and advantages of the present invention will be more apparent from the following detailed description taken in conjunction with the accompanying drawings, in which:

FIG. 1 is a sectional view showing a nonvolatile memory device having SONOS structure according to the prior art;

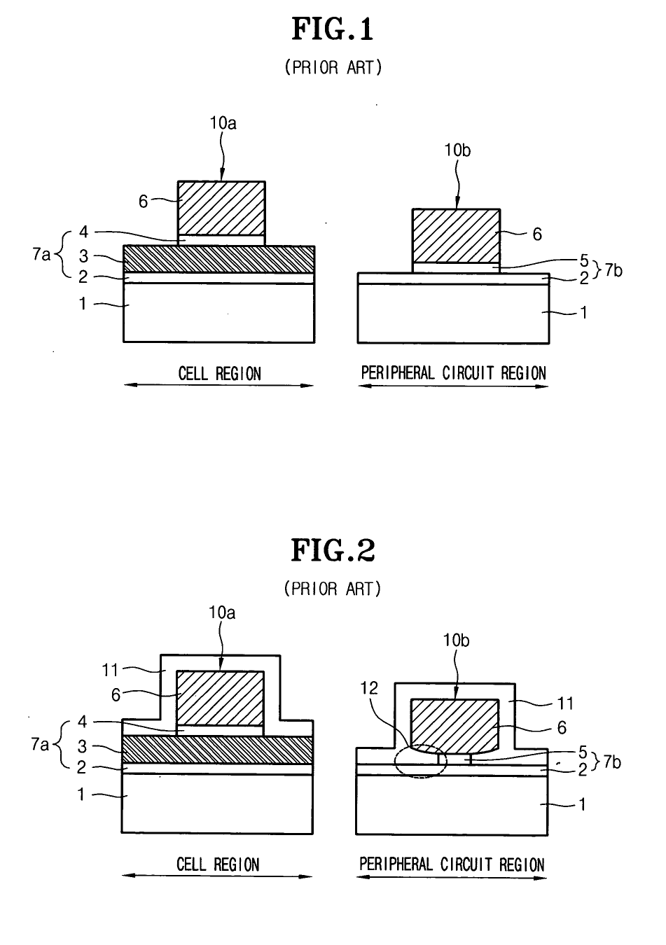

FIG. 2 is a sectional view for explaining the problems of the prior art; and

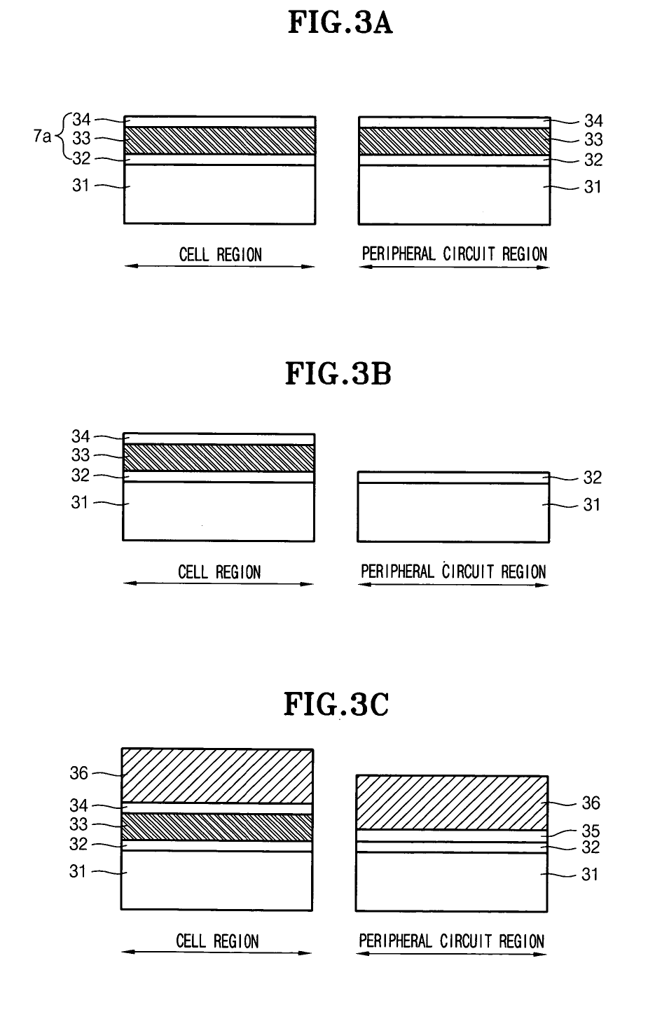

FIGS. 3A to 3F are sectional views showing a series of processes of a method for manufacturing a nonvolatile memory device according to an embodiment of the present invention.

### DETAILED DESCRIPTION OF THE PREFERRED EMBODIMENTS

Hereinafter, a preferred embodiment of the present invention will be described with reference to the accompanying drawings. In the following description and drawings, the same reference numerals are used to designate the same or similar components, and so repetition of the description on the same or similar components will be omitted.

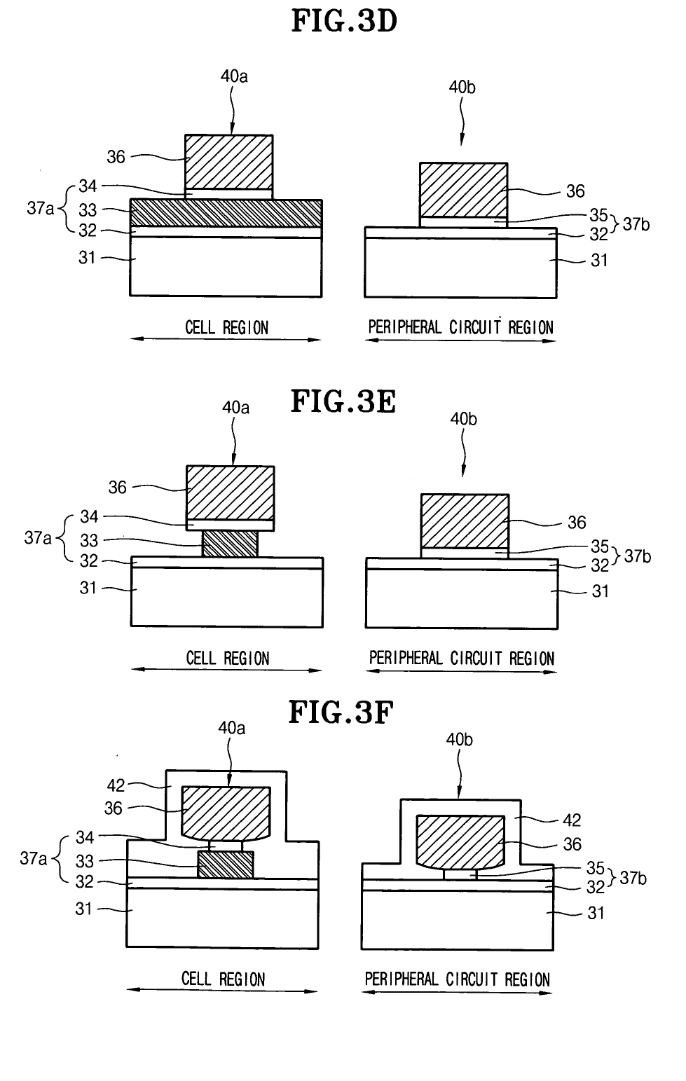

FIGS. 3A to 3F are sectional views showing a series of processes of a method for manufacturing a nonvolatile memory device according to an embodiment of the present invention.

Referring to FIG. 3A, a first oxide film 32 is grown on a silicon substrate 31, which has a cell region and a peripheral circuit region, to a thickness of 10-50 Å in a thermal oxidation mode. A nitride film 33 is then deposited on the first oxide film 32 to a thickness of 50-100 Å and a second oxide film 34 is deposited on the nitride film 33 to a thickness of 30-200 Å in a CVD mode.

Referring to FIG. 3B, a photosensitive film pattern (not shown) is formed on the structure of the substrate in such a manner that the pattern covers the region having SONOS structure formed thereon. The substrate is then dipped into a chemical, e.g., HF or BOE solution, which can etch oxide film while using the photosensitive film pattern as an etching barrier, in order to selective remove the second oxide film 34 from the region having no SONOS structure formed thereon.

After being used as an etching barrier, the photosensitive film pattern is removed according to a conventional technology. The resulting substrate is dipped into a chemical, e.g., H₃PO₄ solution, which can etch nitride film, in order to remove the nitride film 33 from the region having no SONOS structure formed thereon and which is exposed after the second oxide film 34 has been removed. The second oxide film 34 in the region having SONOS structure formed thereon may be partially etched.

The second oxide film 34 and the nitride film 33 can be removed continuously through dry etching. The photosensitive pattern is removed after the etching of the second oxide film 34 and the nitride film 33.

Referring to FIG. 3C, the resulting substrate is subject to another thermal oxidation process to form a third oxide film 35 on the first oxide film 32 in the region having no SONOS structure formed thereon. The final thickness of the gate insulation film of single oxide structure to be formed on the peripheral circuit region is the sum of the thickness of the first oxide film 32 and that of the third oxide film 35, and is approximately 35-200 Å. In order to obtain the desired values of thickness of each film having SONOS structure and that of the oxide films 32 and 35 in the region having no SONOS structure formed thereon, therefore, they must be determined when forming the films in the process shown in FIG. 3A, under consideration of the amount of material added and removed in the processes shown in FIGS. 3B and 3C.

During the thermal oxidation process, the second oxide film 34 made up of CVD oxide film deposited in the region having SONOS structure formed thereon undergoes further densification. The surface of the nitride film 33 is also oxidized partially by the oxidation atmosphere.

A gate conductive film 36 is deposited on the whole resulting substrate. The gate conductive film 36 is made of any one selected from a group consisting of doped polycrystal silicon film, refractory metal film, and metal silicide film, or a combination thereof.

Referring to FIG. 3D, the gate conductive film 36 and the second and third oxide films 34 and 35 are subject to dry etching throughout the cell region and the peripheral circuit region using a conventional technology to form gate electrodes 40a and 40b in the cell region and the peripheral circuit region, respectively. The dry etching is performed as a high-selectivity etching process which minimizes etching damage, because the credibility of the gate insulation film, i.e., the dielectric film, is crucial to the preservation of stored data in the case of a nonvolatile memory device. As a result, the second oxide film 34, the nitride film 33, and the first oxide film 32 below the gate conductive film 36 in the cell region are not etched but remain intact.

Reference numeral 37a refers to a gate insulation film of ONO structure formed in the cell region and 37b refers to a gate insulation film of single oxide structure formed in the peripheral circuit region.

Referring to FIG. 3E, the resulting substrate is dipped into a chemical, e.g., H₃PO₄ solution, which can etch nitride, to remove a part of the nitride film from the lower corner of the gate pattern formed in the cell region. The third, second, and first oxide films 35, 34, and 32 are hardly damaged by the etching which uses H₃PO₄ solution, because oxide is very slowly etched by H₃PO₄ solution. It is preferable to minimize the dipping time using H₃PO₄ solution.

Referring to FIG. 3F, the resulting substrate is subject to a gate light oxidation process, in order to compensate for gate etching damage, and a fourth oxide film 41 is then formed on the surface of the gate electrodes 40a and 40b. In the peripheral circuit region, the lower corner of the gate electrode 40b oxidizes and a bird's-beak 42 occurs as in the case of the prior art. Consequently, the thickness of the gate insulation film 37b of single oxide structure increases. Similarly, the lower corner of the gate electrode 40b in the cell region oxidizes, a bird's-beak 42 occurs, and thereby the thickness of the gate insulation film 37a of ONO structure increases.

As such, the present invention can improve credibility, as well as device characteristics, by increasing the thickness of the gate insulation film, i.e., the dielectric film, in the SONOS structure of the cell region, as well as in the peripheral circuit region.

As mentioned above, the present invention can cause oxidation even to the cell region during gate light etching by etching nitride film in the cell region prior to the gate light etching. This increases the thickness of the gate insulation film of SONOS structure on the lower corner of the gate electrode in the cell region and improves device characteristics and credibility.

Although a preferred embodiment of the present invention has been described for illustrative purposes, those skilled in the art will appreciate that various modifications, additions and substitutions are possible, without departing from the scope and spirit of the invention as disclosed in the accompanying claims.

1. A method for manufacturing a nonvolatile memory device comprising the steps of:
forming a first oxide film, a nitride film, and a second oxide film on a silicon substrate having a cell region and a peripheral circuit region to form SONOS structure in the cell region;
selectively removing the second oxide film and the nitride film in the region having no SONOS structure;
forming a third oxide film on the first oxide film in the region having no SONOS structure;
forming a gate conductive film on the resulting substrate;
etching the gate conductive film and the third and second oxide films to form a gate electrode in the cell region and the peripheral circuit region, respectively;
removing the nitride film from the lower corner of the gate electrode, which has been formed in the cell region; and
performing gate light oxidation to the resulting substrate so that etching damage during formation of the gate electrode is removed.

2. The method for manufacturing a nonvolatile memory device as claimed in claim 1, wherein the first oxide film is formed to a thickness of 10-50 Å in a thermal oxidation process.

3. The method for manufacturing a nonvolatile memory device as claimed in claim 1, wherein the nitride film is formed to a thickness of 50-100 Å.

4. The method for manufacturing a nonvolatile memory device as claimed in claim 1, wherein the second oxide film is formed to a thickness of 30-200 Å in a CVD mode.

5. The method for manufacturing a nonvolatile memory device as claimed in claim 1, wherein the third oxide film has a thickness which, when the thickness of the first oxide film remaining in the peripheral circuit region is added to it, amounts to 35-200 Å.

6. The method for manufacturing a nonvolatile memory device as claimed in claim 1, wherein the gate conductive film is made of any one selected from a group consisting of doped polycrystal silicon film, refractory metal film, and metal silicide film, or a combination thereof.

7. The method for manufacturing a nonvolatile memory device as claimed in claim 1, wherein the gate light oxidation is performed in such a manner that a fourth oxide film is formed on the surface of the gate electrode to a thickness of 50-200 Å.
